(19) United States
(12) Patent Application Publication
(10) Pub. No.: US 2025/0212560 A1
(43) Pub. Date: Jun. 26, 2025

(54) SEMICONDUCTOR EPITAXIAL STRUCTURE AND PREPARATION METHOD THEREOF, AND LIGHT-EMITTING DIODE

(71) Applicant: Xiamen San'an Optoelectronics Co., Ltd., Fujian (CN)

(72) Inventors: Menghsin YEH, Fujian (CN); Zhousheng JIANG, Fujian (CN); Chi-ming TSAI, Fujian (CN); Chungying CHANG, Fujian (CN)

(73) Assignee: Xiamen San'an Optoelectronics Co., Ltd., Fujian (CN)

(21) Appl. No.: 18/967,555

(22) Filed: Dec. 3, 2024

(30) Foreign Application Priority Data
Dec. 26, 2023 (CN) 202311825760.1

(51) Int. Cl. H10H 20/815; H10H 20/01; H10H 20/816; H10H 20/825

(52) U.S. Cl. CPC H10H 20/815; H10H 20/016; H10H 20/8162; H10H 20/825

(57) ABSTRACT

Disclosed are a semiconductor epitaxial structure, a preparation method thereof, and a light-emitting diode. The semiconductor epitaxial structure includes a buffer layer, an N-type semiconductor layer, an active layer, and a P-type semiconductor layer that are sequentially arranged on a substrate. The material of the buffer layer is AlₓIn_{y}Ga_{(1-x-y)}N, wherein 0x and 0≤y. The buffer layer is doped with carbon impurities. The doping concentration of the carbon impurities in the buffer layer is lower than 9E17 atoms/cm³. The present invention grows the buffer layer using a high-temperature growth method. The buffer layer has a lower defect density and a lower content of carbon impurities, making it more possible to facilitate enhancement of the lattice quality of the subsequent epitaxial structure and improve the luminous efficiency and anti-aging capability of the light-emitting diode.

### CROSS-REFERENCE TO RELATED APPLICATION

This application claims the priority benefit of China application serial no. 202311825760.1, filed on Dec. 26, 2023. The entirety of the above-mentioned patent application is hereby incorporated by reference herein and made a part of this specification.

### BACKGROUND

### Technical Field

The invention relates to the technical field of semiconductor devices, and in particular to a semiconductor epitaxial structure and a preparation method thereof, and a light-emitting diode.

### Description of Related Art

Light-emitting diodes (hereinafter referred to as “LEDs”), as a highly influential novel product in the optoelectronic industry, are characterized by their compact size, extended operational lifespan, diverse color spectrum, and low energy consumption. LEDs find extensive application in various domains, including but not limited to illumination, display screens, signal lights, and backlighting. The epitaxial wafer constitutes the core structural component of LEDs. The fabrication process of said epitaxial wafer exerts a substantial impact on the optoelectronic properties of LEDs.

In the process of LED epitaxial growth, due to the lack of substrate materials that match GaN, the GaN thin films are primarily grown on SiC, Si, and sapphire substrates through heteroepitaxial methods. However, significant lattice mismatch and thermal mismatch exist between the heteroepitaxial substrates and the GaN thin films, which may result in the degradation of the crystal quality of the GaN thin films.

In the existing technology, for the growth of GaN epitaxial layers on heterogeneous substrates, it is common practice to insert a buffer layer on the substrate prior to the growth of the epitaxial layer. This buffer layer serves to mitigate issues related to lattice mismatch and thermal expansion coefficient mismatch. However, if the growth quality of the buffer layer is suboptimal, it may adversely affect the quality of the subsequently grown epitaxial layer. Consequently, the development of high-quality buffer layers to enhance the growth quality of epitaxial wafers has become an urgent issue requiring resolution.

### SUMMARY

In light of the aforementioned deficiencies in the existing technology, the purpose of the present invention is to provide a semiconductor epitaxial structure, a preparation method thereof, and a light-emitting diode, with the aim of enhancing the quality of the buffer layer and improving the light output efficiency of the light-emitting diode.

In order to achieve the above purpose and other related purposes, the present invention provides a semiconductor epitaxial structure, which includes a buffer layer, an N-type semiconductor layer, an active layer and a P-type semiconductor layer that are sequentially disposed on a substrate.

The buffer layer is doped with carbon impurities, and the doping concentration of the carbon impurities in the buffer layer is lower than 9E17 atoms/cm³.

According to an aspect of the present invention, a method for preparing a semiconductor epitaxial structure is further provided, including:

Providing a substrate;

Growing a buffer layer on the surface of the substrate, and controlling the growth temperature of the buffer layer to be higher than 600° C.;

Forming an N-type semiconductor layer above the buffer layer;

Forming an active layer above the N-type semiconductor layer; and

Forming a P-type semiconductor layer above the active layer.

According to an aspect of the present invention, a light-emitting diode is further provided. The light-emitting diode includes a substrate, a semiconductor epitaxial structure disposed on the substrate, a P-electrode formed above the P-type semiconductor layer of the semiconductor epitaxial structure, and an N-electrode formed above the N-type semiconductor layer of the semiconductor epitaxial structure, the semiconductor epitaxial structure is the above-mentioned semiconductor epitaxial structure.

Compared with the existing technology, the semiconductor epitaxial structure and the preparation method thereof and the light-emitting diode in the present invention have at least the following advantageous effects:

The semiconductor epitaxial structure in the present invention includes a buffer layer, an N-type semiconductor layer, an active layer and a P-type semiconductor layer that are sequentially disposed on a substrate. The material of the buffer layer is AlₓIn_{y}Ga_{(1-x-y)}N, wherein 0≤x and 0≤y. The buffer layer is doped with carbon impurities. The doping concentration of the carbon impurities in the buffer layer is lower than 9E17 atoms/cm³. The aforementioned buffer layer is grown at high temperature, thereby enabling a reduction in the defect density of the buffer layer and the content of carbon impurities, which facilitates enhancement of the lattice quality of the subsequent epitaxial structure, and improves the luminous efficiency and anti-aging capability of the light-emitting diode.

The light-emitting diode in the present invention includes the above-mentioned semiconductor epitaxial structure and also has the above-mentioned technical effects.

### BRIEF DESCRIPTION OF THE DRAWINGS

FIG. 1 is a schematic structural view of a semiconductor epitaxial structure in Example 1 of the present invention.

FIG. 2A is a secondary ion mass spectrometry (SIMS) analysis graph of the buffer layer in Example 1 of the present invention.

FIG. 2B is an enlarged view of FIG. 2A at a measurement depth of 5.5 μm to 6 μm.

FIG. 3A is an atomic force microscope (AFM) test photo of the active layer in Comparative Example 1 of the present invention.

FIG. 3B is an atomic force microscope (AFM) test photo of the active layer in Example 1 of the present invention.

FIG. 4A is a comparison graph of the XRD test data of the buffer layer in Example 1 of the present invention and the XRD test data of the buffer layer in Comparative Example 1 under the first crystal plane (002) of the buffer layer.

FIG. 4B is a comparison graph of the XRD test data of the buffer layer in Example 1 of the present invention and the XRD test data of the buffer layer in Comparative Example 1 under the second crystal plane (102) of the buffer layer.

FIG. 5 is a comparison graph of the aging time and AIR of the light-emitting diode formed by the semiconductor epitaxial structure in Example 1 of the present invention and the light-emitting diode formed by the semiconductor epitaxial structure in Comparative Example 1.

FIG. 6 is a step flow chart of a method for preparing a semiconductor epitaxial structure in Example 2 of the present invention.

FIG. 7 is a schematic structural view of a light-emitting diode in Example 3 of the present invention.

### DESCRIPTION OF THE EMBODIMENTS

The implementation of the present invention shall be elucidated through specific embodiments hereinafter. Those skilled in the art can readily comprehend other advantages and efficacies of the present invention from the disclosure contained in this specification. The present invention may also be implemented or applied through alternative embodiments. Furthermore, the various details set forth in this specification may be modified or altered based on different perspectives and applications, without departing from the spirit of the present invention. It should be noted that, the embodiments and features thereof described below may be combined with one another in the case of generating no conflict.

The illustrations provided in the embodiments of this invention are intended solely to

elucidate the fundamental concepts of the invention in a schematic manner. The figures depict only those components relevant to the invention, rather than representing the actual number, shape, and dimensions of components as they would appear in practical implementation. In actual implementation, the form, quantity, and proportions of each component may be altered at will, and the layout configuration of components may be more complex. The structures, proportions, and dimensions illustrated in the accompanying drawings of the specification are provided exclusively to complement the content disclosed in the specification, facilitating comprehension and perusal by those skilled in the art. They are not intended to impose restrictive conditions on the implementation of the present invention and therefore lack substantive technical significance. Any modification of structure, alteration of proportional relationships, or adjustment of size, insofar as it does not affect the efficacy that can be produced by this invention or the objectives that can be achieved, should still fall within the scope of technical content disclosed by the present invention.

This embodiment provides a semiconductor epitaxial structure. The semiconductor epitaxial structure includes a buffer layer, an N-type semiconductor layer, an active layer and a P-type semiconductor layer that are sequentially disposed on a substrate.

The buffer layer is doped with carbon impurities, and the doping concentration of the carbon impurities in the buffer layer is lower than 9E17 atoms/cm³. The buffer layer in this embodiment has lower carbon impurity content and better quality, making it possible to facilitate the growth quality of subsequent epitaxial layers.

Optionally, the doping concentration of the carbon impurities in the buffer layer is between 1E16 atoms/cm³ and 9E17 atoms/cm³, or the doping concentration of the carbon impurities in the buffer layer is between 1E15 atoms/cm³ and 9E17 atoms/cm³. By controlling the carbon impurities within this range, it is more possible to facilitate the overall quality of the buffer layer. In the meantime, it is possible to prevent the reduction of carbon impurities due to high-temperature growth, which could adversely affect the overall functionality of the buffer layer.

Optionally, the material of the buffer layer is AlₓIn_{y}Ga_{(1-x-y)}N, wherein OSx and OSy.

Optionally, the thickness of the buffer layer is between 1 nm and 100 nm.

Optionally, the semiconductor epitaxial structure further includes a first undoped layer and a second undoped layer disposed between the buffer layer and the N-type semiconductor layer, wherein:

The first undoped layer is disposed on the buffer layer;

The second undoped layer is disposed on the first undoped layer, and the N-type semiconductor layer is disposed on the second undoped layer.

Optionally, the semiconductor epitaxial structure further includes:

A stress relief layer, which is disposed between the N-type semiconductor layer and the active layer.

Optionally, the semiconductor epitaxial structure further includes:

An electron blocking layer, which is disposed between the active layer and the P-type semiconductor layer.

Optionally, the semiconductor epitaxial structure further includes:

A P-type contact layer, which is disposed on one side of the P-type semiconductor layer away from the active layer.

Optionally, the substrate is a patterned substrate, the surface of the substrate has a plurality of pattern structures disposed at intervals, and the buffer layer is disposed on the surface of the substrate having the pattern structures.

The embodiment further provides a method for preparing a semiconductor epitaxial structure, including:

Providing a substrate;

Growing a buffer layer on the surface of the substrate, and controlling the growth temperature of the buffer layer to be higher than 600° C.;

Forming an N-type semiconductor layer above the buffer layer;

Forming an active layer above the N-type semiconductor layer;

Forming a P-type semiconductor layer above the active layer. This embodiment adopts a high-temperature growth method with a temperature higher than 600° C. to grow the buffer layer. The buffer layer obtained has fewer carbon impurities and better crystal lattice quality.

Optionally, the growth temperature range of the buffer layer is controlled to be between 600° C. and 1000° C., specifically 800° C. and 900° C. The buffer layer grown in this temperature range has fewer carbon impurities and is of higher quality.

Optionally, before forming the N-type semiconductor layer above the buffer layer, the method further includes:

Annealing the buffer layer, and controlling the annealing temperature of the buffer layer to be between 1000° C. and 1100° C.; when the temperature is raised from the growth temperature to the annealing temperature, the raising rate is controlled to be between 80° C./min and 100° C./min. In this way, this embodiment may ensure that a lower defect density and a lower carbon impurity concentration may be obtained without sacrificing the functionality of the buffer layer.

Optionally, before forming the N-type semiconductor layer above the buffer layer, the method further includes:

Forming a first undoped layer on the surface of the buffer layer at the annealing temperature of the buffer layer;

Forming a second undoped layer on the surface of the first undoped layer at a temperature of 1050° C. to 1150° C.

The embodiment further provides a light-emitting diode, including a substrate, a semiconductor epitaxial structure disposed on the substrate, a P-electrode formed above the P-type semiconductor layer of the semiconductor epitaxial structure, and an N-electrode formed above the N-type semiconductor layer of the semiconductor epitaxial structure. The semiconductor epitaxial structure is the above-mentioned semiconductor epitaxial structure. Since the light-emitting diode in this embodiment includes the above-mentioned semiconductor epitaxial structure, the quality of the epitaxial structure in this embodiment is higher, and the light-emitting diode has improved luminous efficiency and anti-aging capability.

This embodiment will be described in detail below with reference to specific examples.

### EXAMPLE 1

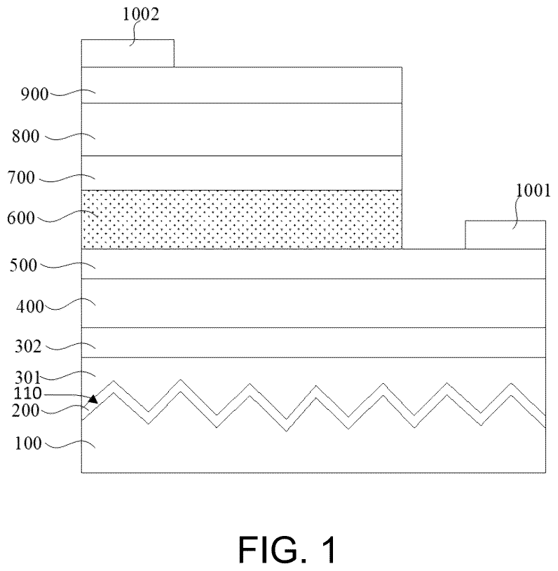

This example provides a semiconductor epitaxial structure. Referring to FIG. 1, the semiconductor epitaxial structure includes a buffer layer 200, an N-type semiconductor layer 400, an active layer 600 and a P-type semiconductor layer 800 which are sequentially disposed on a substrate 100.

Specifically, the buffer layer 200 is formed on the substrate 100. The substrate 100 may be made of a conductive material or an insulating material, and the material may be one of sapphire, aluminum nitride, GaN, and silicon nitride. The most commonly used substrate 100 for LED epitaxial structures is a sapphire substrate. The thickness of the sapphire substrate is between 60 nm and 150 nm. The sapphire substrate is a PSS substrate, that is, aluminum oxide bump patterns of uniform size and uniform spacing are formed on the surface of the sapphire substrate through an etching process. It may be that a part of the height of the aluminum oxide bump patterns is replaced with a material with a lower refractive index than the aluminum oxide.

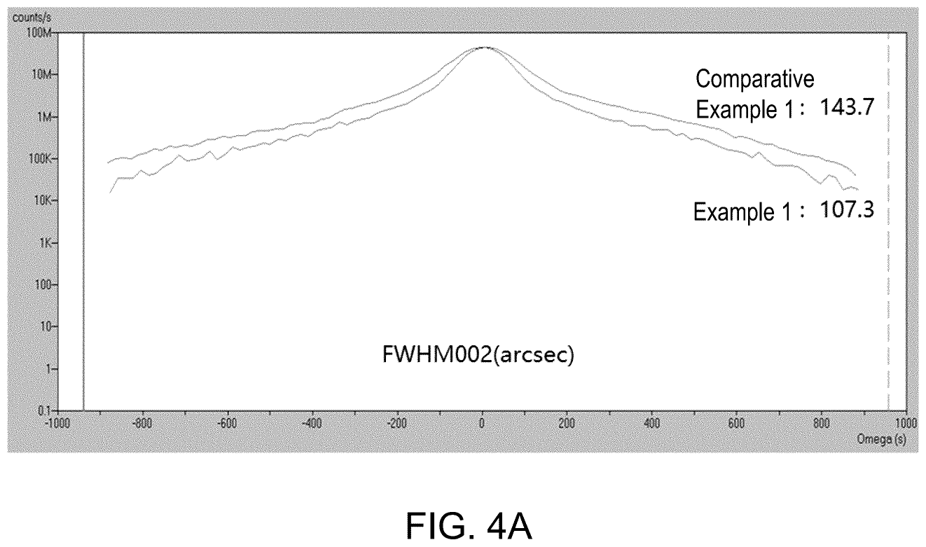

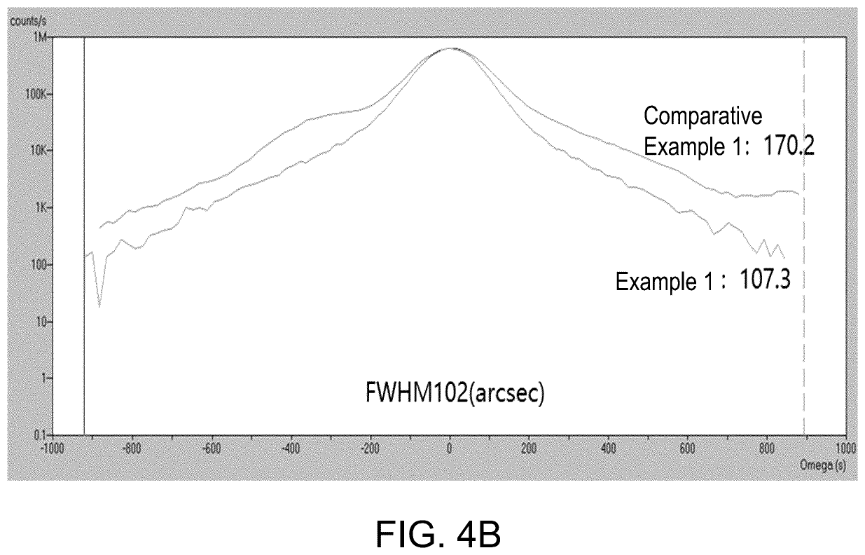

The lattice constant of the buffer layer 200 is between the substrate 100 and the N-type semiconductor layer 400 to reduce the lattice mismatch between the substrate 100 and the N-type semiconductor layer 400. The material of the buffer layer 200 may be AlN, GaN, AlGaN, AlInGaN, etc. In this embodiment, the material of the buffer layer 200 is AlₓIn_{y}Ga_{(1-x-y)}N, wherein 0≤x and 0≤y. The buffer layer 200 is doped with carbon impurities, and the doping concentration of the carbon impurities in the buffer layer 200 is lower than 9E17 atoms/cm³. For example, the doping concentration of the carbon impurities in the buffer layer 200 ranges from 1E¹⁵ atoms/cm³ to 9E17 atoms/cm³, or the doping concentration of the carbon impurities in the buffer layer 200 ranges from 1E16 atoms/cm³to 9E17 atoms/cm³. The thickness of the buffer layer 200 is between 1 nm and 100 nm. When forming the buffer layer 200, the growth temperature thereof is controlled between 600° C. and 1000° C., for example, between 800° C. and 900° C., so as to control the doping concentration of carbon impurities to be lower than 9E17 atoms/cm³. Then, an annealing temperature higher than the growth temperature is adopted for annealing. In this embodiment, the annealing temperature is 1000° C. to 1100° C. When the temperature is raised from the growth temperature to the annealing temperature, the raising rate is controlled to be between 80° C./min and 100° C./min. Setting the range of the growth temperature to the annealing temperature makes it more possible to facilitate reduction of the defect density of the buffer layer 200 and further reduce the content of carbon impurities in the buffer layer 200. After performing a test with an X-ray diffractometer, the buffer layer has a first crystal plane (002) and a second crystal plane (102). Referring to FIG. 4A, the full width at half maximum of the X-ray diffraction peak of the buffer layer on the first crystal plane (002) is 110 arcsec (arc second). Referring to FIG. 4B, the full width at half maximum of the X-ray diffraction peak of the buffer layer on the second crystal plane (102) is less than 160 arcsec. Compared with the buffer layer in the related art, the buffer layer in this embodiment has higher crystal surface quality and lower defect density, making it more possible to enhance the lattice quality of the subsequent epitaxial structure to improve the luminous efficiency and anti-aging capability of the light-emitting diode.

The N-type semiconductor layer 400 may be directly formed on the buffer layer 200, or an undoped layer may be formed first on the buffer layer 200 before forming the N-type semiconductor layer 400 to further reduce the lattice mismatch between the substrate 100 and the N-type semiconductor layer 400. In this embodiment, two undoped layers are formed between the buffer layer 200 and the N-type semiconductor layer 400, namely the first undoped layer 301 and the second undoped layer 302. The material of both the first undoped layer 301 and the second undoped layer 302 is GaN layer. Furthermore, the growth temperature of the first undoped layer 301 is higher than the growth temperature of the second undoped layer 302. For example, the growth temperature of the first undoped layer 301 is formed at the annealing temperature of the buffer layer 200, the annealing temperature is 1000° C. to 1100° C., and the thickness is 1 um to 2um. The growth temperature of the second undoped layer 302 is 1050° C. to 1150° C., and the thickness is 1 μm to 2 μm.

The N-type semiconductor layer 400 is disposed on the second undoped layer 302. The N-type semiconductor layer 400 provides electrons by deliberately doping N-type impurities, which may be Si, Ge, Sn, Se, and Te. In this embodiment, the N-type impurity is Si, and the material of the N-type semiconductor layer 400 is an N-GaN layer. The thickness of the N-type semiconductor layer 400 is 1.5 μm to 4 μm, and the N-type semiconductor layer 400 may be grown by controlling the growth temperature to be between 1030° C. and 1130° C.

In order to release the stress between the N-type semiconductor layer 400 and the active layer 600, optionally, the semiconductor epitaxial structure further includes a stress relief layer 500. The stress relief layer 500 is disposed between the N-type semiconductor layer 400 and the active layer 600 and is configured to release the stress between the N-type semiconductor layer 400 and the active layer 600 during the epitaxial growth process. In this embodiment, the thickness of the stress relief layer 500 is 100 nm to 400 nm, the material is InGaN or GaN, and the stress relief layer is doped with silicon.

The active layer 600 is disposed on the stress relief layer 500 and is a region where electrons and holes recombine to generate light. The active layer 600 includes alternately arranged barrier layers and well layers, and the alternating period of the barrier layers and well layers is between 5 pairs and 15 pairs. The barrier layer is an AlGaN layer or a GaN layer, and the well layer is an InGaN layer. By adjusting the content of In of InGaN, the energy level band gap may be adjusted, thereby adjusting the emission wavelength of the active layer 600. In this embodiment, the barrier layer of the active layer 600 is GaN, the well layer is InGaN, and the growth temperature is between 750° C. and 900° C.

The P-type semiconductor layer 800 is disposed above the active layer 600. The P-type semiconductor layer 800 may provide holes through P-type impurities, and the P-type impurities may be Mg, Zn, Ca, Sr, and Ba. In this embodiment, the P-type impurity of the P-type semiconductor layer 800 is Mg, and the material of the P-type semiconductor layer 800 is P-AlInGaN, specifically Al_{c}In_{d}Ga_{(1-c-d)}N, wherein 0≤c and 0≤d. The growth temperature of the P-type semiconductor layer 800 is between 800° C. and 1050° C. Optionally, in order to prevent electron overflow of the active layer 600, the semiconductor epitaxial structure further includes an electron blocking layer 700, which is disposed between the P-type semiconductor layer 800 and the active layer 600. The material of the electron blocking layer 700 is AlₐIn_{b}Ga_{(1-a-b)}N, wherein 0≤a and 0≤b.

The P-type contact layer 900 is formed on the P-type semiconductor layer 800. The P-type doping concentration of the P-type contact layer 900 is greater than the P-type doping concentration of the P-type semiconductor layer 800. The growth temperature of the P-type contact layer 900 is the same as the growth temperature of the P-type semiconductor layer 800, which is 800° C. to 1050° C. The material of the P-type contact layer 900 is AlInGaN.

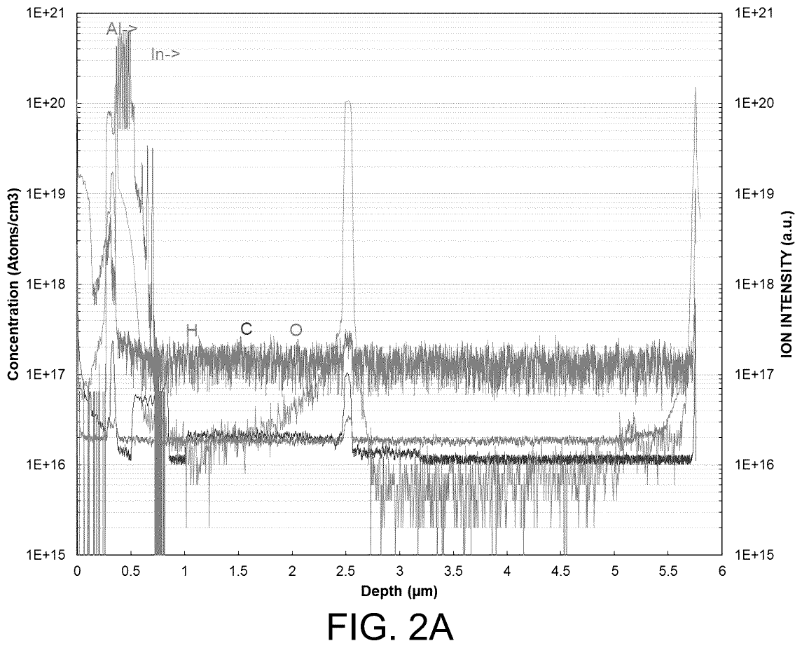

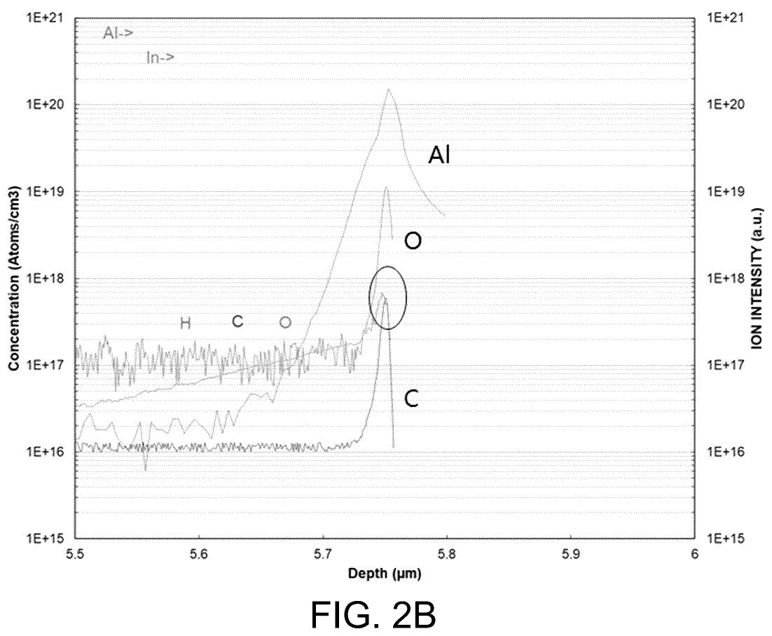

SIMS secondary ion mass spectrometry analysis is performed on the buffer layer in this example. The SIMS secondary ion mass spectrometry analysis is shown in FIG. 2A and FIG. 2B. It can be seen from the figure that the content of carbon element in the buffer layer 200 in this example is not higher than 9E17 atoms/cm³. For example, the doping concentration of carbon impurities in the buffer layer 200 ranges from 1E16 atoms/cm³to 9E17 atoms/cm³. In comparison, the test value of doping concentration of the carbon impurity of the buffer layer 200 is generally higher than the actual test value. Therefore, the actual content of the carbon impurity in the buffer layer 200 is between 9E15 atoms/cm³ and 9E17 atoms/cm³, or lower. Therefore, the buffer layer in the present example has less content of carbon impurity and lower defect density.

### COMPARATIVE EXAMPLE 1

This comparative example provides a semiconductor epitaxial structure. The similarities between the semiconductor epitaxial structure in the comparative example and the semiconductor epitaxial structure in Example 1 will not be repeated here. The differences between them are as follows:

The growth temperature of the buffer layer in this comparative example is in the range of 300° C. to 500° C.

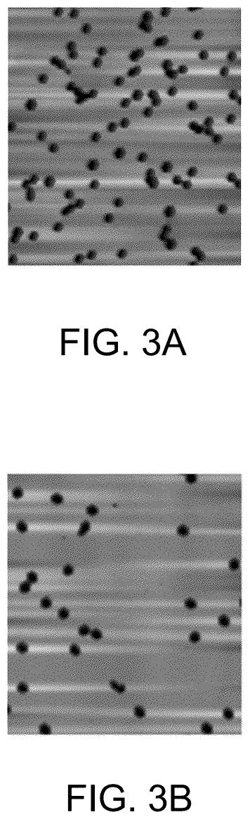

The active layer grown above the buffer layer in Example 1 and the active layer grown above the buffer layer in Comparative Example 1 are subjected to atomic force microscope (AFM) testing. From the comparison, it can be seen that the V-shaped pits in the active area in Comparative Example 1 are denser, as shown in FIG. 3A. In this embodiment 1, the density of V-shaped pits in the active area is significantly lower, as shown in FIG. 3B. It can be seen that the buffer layer in the Example 1 has a lower defect density and a higher crystal surface quality. The epitaxial layer or active layer subsequently grown on the buffer layer has a lower defect density and a higher lattice quality.

The buffer layer grown in Example 1 and the buffer layer formed in Comparative Example 1 are subjected to X-ray diffraction (XRD) tests of different crystal planes. In order to facilitate the determination and differentiation of crystal directions and crystal planes in different directions in the crystal, the Miller index is used internationally to uniformly calibrate the crystal orientation index and crystal plane index, wherein (002) and (102) refer to the crystal planes with Miller indexes of (002) and (102) respectively. Referring to FIG. 4A, the crystal plane quality is tested on the first crystal plane (002) of the buffer layer. The full width at half maximum (FWHM) of the X-ray diffraction peak of the buffer layer in Comparative Example 1 is 143.7 arcsec. The full width at half maximum of the X-ray diffraction peak of the buffer layer in Example 1 is 107.3 arcsec. Referring to FIG. 4B, the crystal plane quality is tested on the second crystal plane (102) of the buffer layer. The full width at half maximum of the X-ray diffraction peak of the buffer layer in Comparative Example 1 is 170.2 arcsec. The full width at half maximum of the X-ray diffraction peak of the buffer layer in Example 1 is 155.3 arcsec. It can be seen that in this Example 1, the peak width value of the X-ray diffraction peak of the buffer layer is smaller and the wave peak is narrower. Therefore, the buffer layer in this example has higher lattice quality and lower defect density.

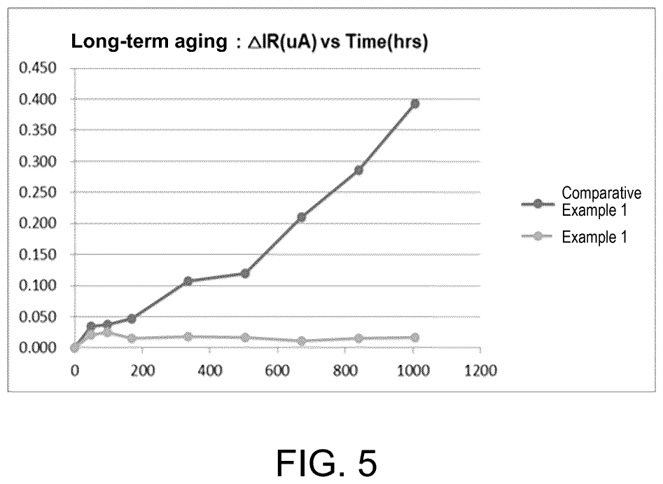

The light-emitting diode formed from the semiconductor epitaxial structure in Example 1 and the light-emitting diode formed from the semiconductor epitaxial structure in Comparative Example 1 (except for the difference in the buffer layer, the rest of the structures are the same as Example 1) are subjected to an aging test, as shown in FIG. 5, the AIR of the light-emitting diode in Example 1 basically remains unchanged within 1000 hours of use. It can be seen that the light-emitting diode of Example 1 has improved anti-aging capability.

In summary, the buffer layer in the semiconductor epitaxial structure in Example 1 of the present invention has a lower C doping concentration and less defects, which may improve the lattice quality of subsequent GaN growth and reduce light absorption and aging leakage conditions. The density of V-shaped pits in the active layer grown above the buffer layer is lower and the epitaxial quality is higher. The resulting light-emitting diode has improved luminous efficiency and anti-aging capability.

### EXAMPLE 2

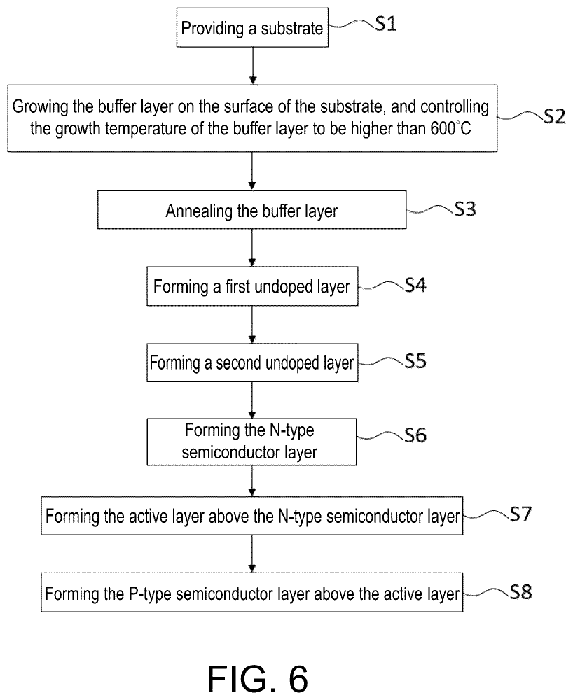

This Example provides a method for preparing a semiconductor epitaxial structure. Referring to FIG. 6 and combined with FIG. 1, the preparation method includes:

S1: Providing a substrate 100;

Specifically, the substrate 100 may be made of a conductive material or an insulating material, and the material may be one of sapphire, aluminum nitride, GaN, and silicon nitride. The substrate 100 in this example is a sapphire substrate 100, and a pattern structure 110 is formed on the surface of the sapphire substrate 100. Before forming the buffer layer 200 on the surface of the sapphire substrate 100, the sapphire pattern substrate 100 is first put into a metal organic chemical vapor deposition (MOCVD) chamber and the temperature is raised to 1000° C. to 1200° C., and the substrate 100 is processed under a hydrogen atmosphere.

S2: Growing the buffer layer 200 on the surface of the substrate 100, and controlling the growth temperature of the buffer layer 200 to be between 600° C. and 1000° C.;

Specifically, after the sapphire substrate 100 is processed, the temperature of the deposition chamber is controlled to be 600° C. to 1000° C., for example, 800° C. to 900° C., and a gas source containing Al, In, Ga and N is introduced into the deposition chamber to form an AlInGaN buffer layer 200 having a thickness ranging from 10 nm to 40 nm.

S3: Optionally, annealing the buffer layer 200;

Specifically, the growth temperature is raised to a range of 1000° C. to 1100° C. and the buffer layer 200 is annealed. The raising rate of the temperature is controlled to be 100° C./min and the annealing time is 1 min to 5 min to obtain a buffer layer 200 with a carbon doping concentration lower than 9E17 atoms/cm³. Compared with the existing buffer layer 200, the buffer layer 200 obtained in this example has lower carbon content, lower angular peak width, lower defect density, and higher lattice quality.

S4: Optionally, forming a first undoped layer 301 on the surface of the buffer layer 200;

Trimethylgallium is continuously introduced at the annealing temperature to grow a first undoped layer 301 with a thickness of 1 μm to 2 μm. The first undoped layer 301 is an undoped gallium nitride layer.

S5: Optionally, forming a second undoped layer 302 on the surface of the first undoped layer 301;

The temperature is continuously raised to 1050° C. to 1150° C. to grow a second undoped layer 302 of 1 μm to 2 μm. The material of the second undoped layer 302 is the same as that of the first undoped layer 301.

S6: Forming the N-type semiconductor layer 400 above the buffer layer 200;

Specifically, after the second undoped layer 302 is formed, the temperature is lowered

to 1030° C. to 1130° C. to grow gallium nitride with a thickness of 1.5 μm to 4 μm, and monosilane introduced for doping to form the N-type semiconductor layer 400.

After the N-type semiconductor layer 400 is formed, the temperature is lowered to 800° C. to 950° C., a stress relief layer 500 of a thickness of 100 nm to 400 nm is grown, and monosilane is introduced for doping.

S7: Forming the active layer 600 above the N-type semiconductor layer 400;

Specifically, after the stress relief layer 500 is formed, the temperature is lowered to 750° C. to 900° C., and the active layer 600 is grown on the stress relief layer 500. The active layer 600 is a multi-quantum well layer, the material thereof is InGaN/GaN, and the growth cycle is 5˜15.

After the active layer 600 or the multi-quantum well layer is formed, the temperature is

raised to 800° C. to 950° C. After the multi-quantum well layer is formed, a u-type or P-type electron blocking layer 700 is grown. The material of the electron blocking layer 700 is AlₐIn_{b}Ga_{(1-a-b)}N, wherein 0≤a and 0≤b.

S8: Forming the P-type semiconductor layer 800 above the active layer 600.

Specifically, after the electron blocking layer 700 is formed, a P-type semiconductor layer 800 is grown on the electron blocking layer 700 at a temperature of 800° C. to 1050° C. The material of the P-type semiconductor layer 800 is Al_{c}InₐGa_{(1-c-d)}N, wherein 0≤c and 0≤d.

After the P-type semiconductor layer 800 is formed, a heavily doped P-type contact layer 900 is grown on the P-type semiconductor layer 800 at a temperature of 800° C. to 1050° C. The material of the P-type contact layer 900 is the same as that of the P-type semiconductor layer 800.

The buffer layer obtained by using the preparation method of the semiconductor epitaxial structure in this example has a lower C doping concentration and less defects, which may improve the lattice quality of subsequent GaN growth, reduce light absorption and aging leakage, thereby improving the luminous efficiency and anti-aging capability of the LED.

### EXAMPLE 3

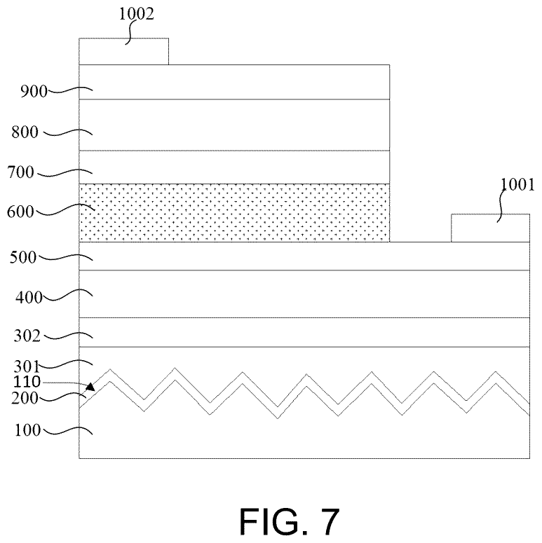

This example provides a light-emitting diode. Referring to FIG. 7, the light-emitting diode includes a substrate 100, a semiconductor epitaxial structure disposed on the substrate 100, a P-electrode 1002 formed on the P-type semiconductor layer 800 of the semiconductor epitaxial structure, and an N-electrode 1001 formed above the N-type semiconductor layer 400 of the semiconductor epitaxial structure.

Specifically, the substrate 100 may be made of a conductive material or an insulating

material, and the material may be one of sapphire, aluminum nitride, GaN, and silicon nitride. The most commonly used substrate 100 for LED epitaxial structures is a sapphire substrate 100. The thickness of the sapphire substrate 100 is between 60 nm and 150 nm. The sapphire substrate 100 is a PSS substrate 100, that is, aluminum oxide bump patterns of uniform size and uniform spacing are formed on the surface of the sapphire substrate 100 through an etching process. It may be that a part of the height of the aluminum oxide bump patterns is replaced with a material with a lower refractive index than the aluminum oxide. The buffer layer 200 in the semiconductor epitaxial structure is formed on one side of the patterned substrate 100 having a pattern structure 110, and the semiconductor epitaxial structure is the same as the epitaxial structure in Example 1, so related details are not repeated here.

The light-emitting diode may be a chip with a horizontal structure or a vertical structure. In this example, the chip is exemplified with a horizontal structure. As shown in FIG. 7, a transparent electrode layer (not shown) is further disposed on the P-type contact layer 900. For example, the transparent electrode layer may be ITO or GTO. The P-electrode 1002 is located on the transparent electrode layer, and is electrically connected to the P-type semiconductor layer 800 through the transparent electrode layer and the P-type contact layer 900. The semiconductor epitaxial structure is etched downward from the P-type contact layer 900 and formed with a step. The surface of the step exposes the stress relief layer 500, the N-electrode 1001 is formed on the surface of the stress relief layer 500, and is electrically connected to the N-type semiconductor layer 400.

In summary, the semiconductor epitaxial structure in the present invention includes a buffer layer, an N-type semiconductor layer, an active layer and a P-type semiconductor layer that are sequentially disposed on a substrate. The material of the buffer layer is AlₓIn_{y}Ga_{(1-x-y)}N, wherein 0≤x and 0≤y. The buffer layer is doped with carbon impurities. The doping concentration of the carbon impurities in the buffer layer is lower than 9E17 atoms/cm³. The above-mentioned buffer layer is grown at high temperature, thus reducing the defect density and content of carbon impurity of the buffer layer, and making it more possible to facilitate enhancement the lattice quality of the subsequently grown epitaxial structure and improve the luminous efficiency and anti-aging capability of the light-emitting diode.

The light-emitting diode in the present invention includes the above-mentioned semiconductor epitaxial structure and also has the above-mentioned technical effects.

The above embodiments only illustrate the principles and effects of the present invention, but are not intended to limit the present invention. Anyone familiar with this technology can modify or change the above embodiments without departing from the spirit and scope of the invention. Therefore, all equivalent modifications or changes made by those with ordinary knowledge in the technical field without departing from the spirit and technical ideas disclosed in the present invention shall still be covered by the claims of the present invention.

What is claimed is:

1. A semiconductor epitaxial structure, comprising a buffer layer, an N-type semiconductor layer, an active layer and a P-type semiconductor layer that are sequentially disposed on a substrate;
wherein the buffer layer is doped with carbon impurities, and a doping concentration of the carbon impurities in the buffer layer is lower than 9E17 atoms/cm³.

2. The semiconductor epitaxial structure according to claim 1, wherein the doping concentration of the carbon impurities in the buffer layer is between 1E16 atoms/cm³and 9E17 atoms/cm³.

3. The semiconductor epitaxial structure according to claim 1, wherein the doping concentration of the carbon impurities in the buffer layer is between 1E15 atoms/cm³and 9E17 atoms/cm³.

4. The semiconductor epitaxial structure according claim 1, wherein a material of the buffer layer is AlₓIn_{y}Ga_{(1-x-y)}N, wherein 0≤x and 0≤y.

5. The semiconductor epitaxial structure according to claim 1, wherein a thickness of the buffer layer is between 1 nm and 100 nm.

6. The semiconductor epitaxial structure according to claim 1, wherein the semiconductor epitaxial structure further comprises a first undoped layer and a second undoped layer disposed between the buffer layer and the N-type semiconductor layer, wherein:
the first undoped layer is disposed on the buffer layer;
the second undoped layer is disposed on the first undoped layer, and the N-type semiconductor layer is disposed on the second undoped layer.

7. The semiconductor epitaxial structure according to claim 1, further comprising:
a stress relief layer, disposed between the N-type semiconductor layer and the active layer.

8. The semiconductor epitaxial structure according to claim 1, further comprising:
an electron blocking layer, disposed between the active layer and the P-type semiconductor layer.

9. The semiconductor epitaxial structure according to claim 1, further comprising:
a P-type contact layer, disposed on one side of the P-type semiconductor layer away from the active layer.

10. The semiconductor epitaxial structure according to claim 1, wherein a surface of the substrate has a plurality of pattern structures disposed at intervals, and the buffer layer is disposed on the surface of the substrate having the pattern structures.

11. A method for preparing a semiconductor epitaxial structure, comprising:
providing a substrate;
growing a buffer layer on a surface of the substrate, and controlling a growth temperature of the buffer layer to be higher than 600° C.;
forming an N-type semiconductor layer above the buffer layer;
forming an active layer above the N-type semiconductor layer; and
forming a P-type semiconductor layer above the active layer.

12. The method for preparing the semiconductor epitaxial structure according to claim 11, wherein the growth temperature of the buffer layer is controlled to be between 600° C. and 1000° C.

13. The method for preparing the semiconductor epitaxial structure according to claim 11, wherein before forming the N-type semiconductor layer above the buffer layer, the method further comprises:
annealing the buffer layer, and controlling an annealing temperature of the buffer layer to be between 1000° C. and 1100° C.; and
wherein when the growth temperature is raised to the annealing temperature, a raising rate is controlled to be between 80° C./min and 100° C./min.

14. The method for preparing the semiconductor epitaxial structure according to claim 13, wherein before forming the N-type semiconductor layer above the buffer layer, the method further comprises:
forming a first undoped layer on a surface of the buffer layer at the annealing temperature of the buffer layer;
forming a second undoped layer on a surface of the first undoped layer at a temperature of 1050°° C. to 1150° C.

15. A light-emitting diode, comprising a substrate, a semiconductor epitaxial structure disposed on the substrate, a P-electrode formed above a P-type semiconductor layer of the semiconductor epitaxial structure, and an N-electrode formed above an N-type semiconductor layer of the semiconductor epitaxial structure, wherein the semiconductor epitaxial structure is the semiconductor epitaxial structure according to claim 1.
